(19) United States
(12) Patent Application Publication
(10) Pub. No.: US 2010/0159696 A1
(43) Pub. Date: Jun. 24, 2010

(54) MICROLENS MASK OF IMAGE SENSOR AND METHOD FOR FORMING MICROLENS USING THE SAME

(76) Inventor: Jong Man Kim, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/644,702

(22) Filed: Dec. 22, 2009

(30) Foreign Application Priority Data
Dec. 24, 2008 (KR) 10-2008-0132879

(51) Int. Cl. H01L 21/3205; G03F 1/00

(52) U.S. Cl. 438/674; 430/5; 438/70; 257/E21.294

(57) ABSTRACT

Provided are a microlens mask of an image sensor and a method for forming a microlens using the same. In the method, an insulating layer is formed on a semiconductor substrate comprising a photodiode and a transistor. A passivation layer is formed on the insulating layer. A color filter layer is formed on the insulating layer vertically corresponding to the photodiode through the passivation layer. A microlens photoresist layer is formed over an entire surface of the semiconductor substrate. A microlens mask is formed on the microlens photoresist corresponding to the color filter layer. A one-time exposure process is performed at a light intensity of about 450/0 to about 550/0 dose/focus. The microlens photoresist layer is patterned to form a patterned microlens photoresist layer by removing the photoresist subjected to the exposure process. The patterned microlens photoresist layer is reflowed to form the microlens.

### CROSS-REFERENCE TO RELATED APPLICATION

This application claims the benefit under 35 U.S.C. §119 of Korean Patent Application No. 10-2008-0132879, filed Dec. 24, 2008, which is incorporated herein by reference in its entirety.

### BACKGROUND

The present disclosure relates to a microlens mask of an image sensor and a method for forming a microlens using the same.

FIG. 1 is a cross-sectional view illustrating an image sensor after a microlens photoresist layer 40 is formed.

Referring to FIG. 1, an insulating layer 10 is formed on a substrate (not shown) provided with photodiodes and transistors. The insulating layer 10 is formed of a material such as Undoped Silicate Glass (USG). A metal pad 12, a metal interconnection (not shown), and a contact plug (not shown) may be formed in the insulating layer 10.

A Silicon Nitride (SiN) layer 20 is formed on the insulating layer 10. A color filter layer 30 is formed on the insulating layer 10 to penetrate through the SiN layer 20.

Also, a microlens photoresist layer 40 is formed over the entire surface of the substrate including the color filter layer 30, the SiN layer 20, and the metal pad 12.

FIG. 2 is a cross-sectional view illustrating an image sensor after a mask 50 is formed to remove the photoresist layer 40 on the metal pad 12. FIG. 3 is a top view illustrating photoresist residues on the metal pad 12.

The mask 50 is formed on the microlens photoresist 40 such that the pad 12 may be opened. A first exposure process is performed at a light intensity of about 330/0 (dose/focus) to remove the photoresist layer 40 on the pad 12. Here, since the light intensity of the first exposure process is adjusted to be low, residues of the photoresist remain on the pad 12 after development of the photoresist. FIG. 3 shows an image of photoresist residues remaining on a metal pad after removing the photoresist layer according to the related art.

FIG. 4 is a cross-sectional view illustrating an image sensor after a microlens mask 60 is formed. FIG. 5 is a top view illustrating the microlens mask 60. FIG. 6 is a cross-sectional view illustrating an image sensor after a microlens 42 is formed.

Referring to FIG. 4, after the mask 50 is removed, the microlens mask 60 as shown in FIG. 5 is formed on the color filter layer 30.

Next, a second exposure process is performed at a light intensity of about 300/0 (dose/focus) using the microlens mask 60 as an exposure mask. In this case, the residues of the photoresist remaining on the pad 12 are able to be removed by the second exposure process.

Thereafter, the microlens mask 60 is removed, and the photoresist layer 40 subjected to the second exposure process, including the photoresist residues on the pad 12, is removed through a development process. The photoresist on the color filter layer 30 that was covered by the microlens mask 60 remains as a microlens photoresist pattern.

Finally, the microlens photoresist pattern formed on the color filter layer 30 obtains a convex shape through a reflow process, and thus the formation of the microlens 42 is completed, as shown in FIG. 6.

Thus, the exposure process is twice performed at a low light intensity. This is because, when the photoresist layer 40 on the pad 12 is completely removed by a one-time exposure at a high light intensity of about 500/0 (dose/focus), an interval between the microlens photoresist patterns on the color filter layer 30 is increased up to about 0.3 an to about 0.5 μm.

This results in an increase of an interval between the microlenses 42 and a reduction of the sensitivity of the image sensor.

However, there are limitations in that, although the residues of the photoresist on the pad 12 are removed through the two exposure processes, the increase of the interval of the microlens photoresist pattern is inevitable, the process thereof becomes complicated, and the manufacturing time and cost are increased.

### BRIEF SUMMARY

Embodiments provide a microlens mask of an image sensor and a method for forming a microlens using the same, which can remove a photoresist on a metal pad through a one-time exposure process and maintain an interval of a microlens photoresist pattern on a color filter layer to be constant when the microlens photoresist on the metal pad is removed through the exposure process.

Embodiments provide a microlens mask of an image sensor and a method for forming a microlens using the same, the microlens mask being an exposure mask used to pattern a microlens photoresist layer and comprising a plurality of patterns forming a pentagonal or hexagonal array, sides of which are adjacent to each other, and wherein the patterns of the pentagonal or hexagonal array have an interval spacing of about 0.045 μm to about 0.055 μm.

In one embodiment, a method for forming a microlens comprises: forming an insulating layer on a semiconductor substrate comprising a photodiode and a transistor, the insulating layer comprising a metal pad exposed to the outside; forming a passivation layer on the insulating layer; forming a color filter layer on the insulating layer vertically corresponding to the photodiode, the color filter layer passing through the passivation layer; forming a microlens photoresist layer over an entire surface of the semiconductor substrate including the color filter layer, the passivation layer, and the metal pad; forming a microlens mask on the microlens photoresist corresponding to the color filter layer, the microlens mask comprising a plurality of patterns forming a pentagonal or hexagonal array, sides of which are adjacent to each other, and wherein the patterns of the pentagonal or hexagonal array have an interval of about 0.045 μl to about 0.055 μm; performing a one-time exposure process at a light intensity of about 450/0 to 550/0 (dose/focus); patterning the microlens photoresist to form a patterned photoresist layer by removing the exposed microlens photoresist; and reflowing the patterned microlens photoresist layer to form the microlens.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating an image sensor after a photoresist pattern layer for microlens is formed.

FIG. 2 is a cross-sectional view illustrating an image sensor after a mask is formed to remove a photoresist layer on a pad.

FIG. 3 is a top view illustrating residues of a photoresist on a pad.

FIG. 4 is a cross-sectional view illustrating an image sensor after a microlens mask is formed.

FIG. 5 is a top view illustrating the microlens mask.

FIG. 6 is a cross-sectional view illustrating an image sensor after a microlens is formed.

FIG. 7 is a cross-sectional view illustrating an image sensor after a photoresist layer for microlens is formed according to an embodiment of the present invention.

FIG. 8 is a cross-sectional view illustrating an image sensor after a microlens mask is formed according to an embodiment of the present invention.

FIG. 9 is a top view illustrating a microlens mask according to an embodiment.

FIG. 10 is a cross-sectional view illustrating an image sensor after a microlens is formed according to an embodiment of the present invention.

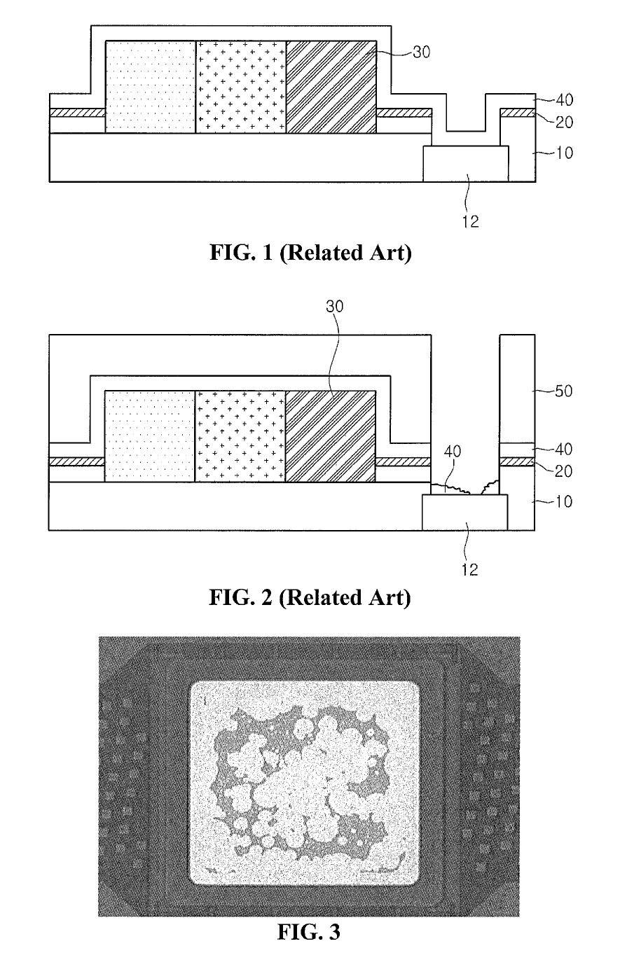

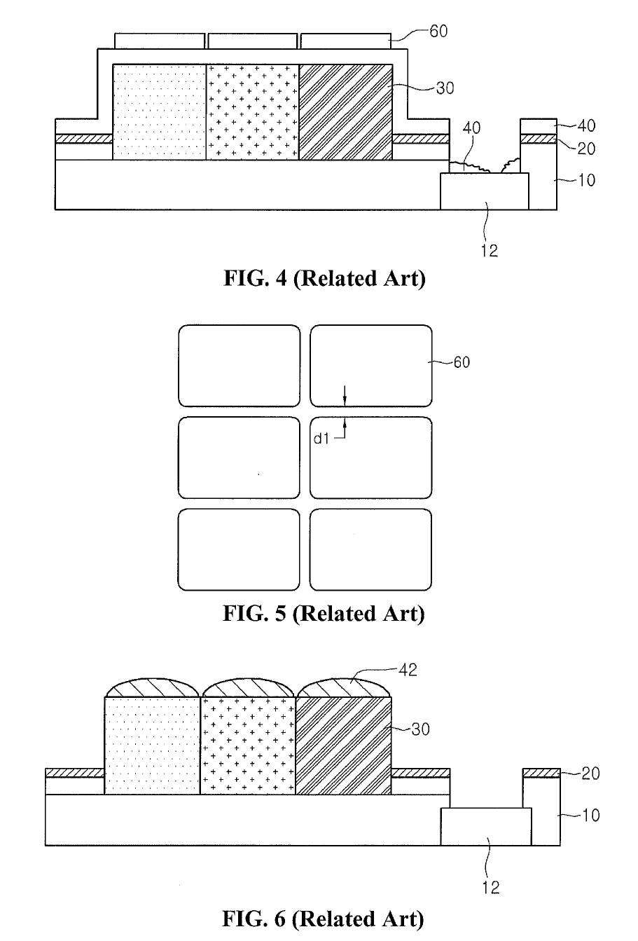

### DETAILED DESCRIPTION

Hereinafter, a microlens mask of an image sensor and a method for forming a microlens using the same according to exemplary embodiments will be described in detail with reference to the accompanying drawings.

Hereinafter, for description of exemplary embodiments, detailed descriptions of related known functions or configurations are omitted in order not to obscure the subject matter of the present invention. Thus, only core components, which are directly related to the technical spirit of the present invention, will be mentioned below.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

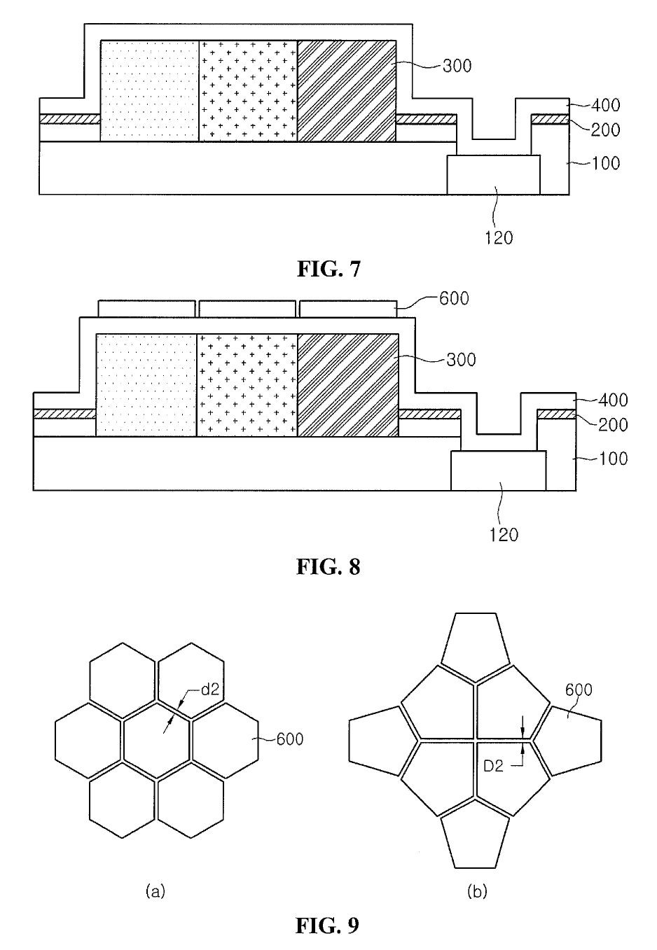

FIG. 7 is a cross-sectional view illustrating an image sensor after a photoresist layer for microlens is formed according to an embodiment.

Referring to FIG. 7, an insulating layer 100 is formed on a substrate (not shown) provided with photodiodes and transistors. The insulating layer 100 is formed of a material such as Undoped Silicate Glass (USG). A metal pad 120, a metal interconnection (not shown), and a contact plug (not shown) may be formed in the insulating layer 100.

The photodiode of the semiconductor substrate constitutes a unit pixel of the image sensor, and is connected to a plurality of transistors controlling transmission and output of charges stored in the photodiode.

For example, the transistors may be formed in a semiconductor substrate region between photodiodes through semiconductor processes, and may include a transfer transistor Tx, a reset transistor Rx, a select transistor Sx, and an access transistor Ax for each unit pixel.

Also, the insulating layer 100 may be formed in a multiple stacked structure. The metal pad is formed on the uppermost insulating layer 100 to be exposed to the outside.

A SiN layer 200 is formed on the insulating layer 100. A color filter layer 300 is formed on the insulating layer 100 to penetrate through the SiN layer 200.

The SiN layer 120 serves as a passivation layer.

The color filter layer 300 is vertically formed in a region corresponding to the photodiode.

After forming the color filter layer 300, a microlens photoresist layer 400 is formed on the entire substrate including the color filter layer 300, the SiN layer 200, and the metal pad 120.

FIG. 8 is a cross-sectional view illustrating an image sensor after a microlens mask 600 is formed on the microlens photoresist layer 400 according to an embodiment. FIG. 9 is a top view illustrating microlens mask 600 arrangements according to an embodiment.

Referring to FIG. 8, the microlens mask 600 is formed on the microlens photoresist layer 400, and an exposure process is performed thereon.

The microlens mask 600 may have a hexagonal shape similar to a honey comb pattern as shown in FIG. 9A or a pentagonal shape similar to a snow crystal pattern as shown in FIG. 9B.

Each pattern of the microlens mask 600 corresponds to one color filter of the color filter layer 300 and one microlens to be formed thereon.

The patterns are formed spaced to have intervals d2 of about 0.045 on to about 0.055 μm.

Accordingly, the microlens mask 600 may be compactly arranged while intervals between adjacent sides of the patterns are maintained constant and minimized. Accordingly, light-concentration efficiency can be enhanced upon exposure, and an increase of the interval between the patterns may be minimized due to high light intensity.

The exposure process may be once performed at a relatively high light intensity of about 450/0 to about 550/0 (dose/focus). In this case, the microlens photoresist layer 400 on the metal pad 120 may be completely removed by the single exposure process.

The microlens mask 600 according to this embodiment allows the interval between the microlens photoresist patterns to be maintained at less than about 0.15 μm even though the interval spacing increases due to the exposure. Accordingly, it is possible to inhibit reduction of the sensitivity of the image sensor.

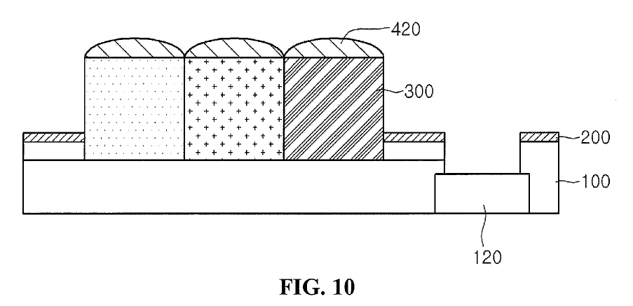

FIG. 10 is a cross-sectional view illustrating an image sensor after a microlens 420 is formed according to an embodiment.

For example, after performing the single exposure process, the microlens mask 600 is removed. Then, a development process is performed to remove the photoresist layer 400 that was not covered by the microlens mask 600.

Accordingly, a photoresist pattern for microlens may be formed on the color filter layer 300 that maintains the interval of less than about 0.15 μm.

Finally, the microlens photoresist pattern on the color filter layer 300 is provided having a convex shape through a reflow process as shown in FIG. 10, and thus a microlens 420 is formed.

A microlens mask of an image sensor and a method for forming a microlens using the same according to the exemplary embodiments have the following advantages.

First, since the structure (shape and interval) of a microlens mask is improved, and the light intensity is adjusted to be high in the exposure process, a microlens photoresist on a metal pad may be completely removed through the one-time exposure process.

Second, an increase of an interval between microlenses can be inhibited even when the light intensity of the exposure process is increased in order to remove the microlens photoresist on the metal pad in a single exposure process. Thus, the sensitivity of an image sensor can be maintained stable, and the yield rate can be enhanced.

Third, since the microlens photoresist on the metal pad is completely removed through the one-time exposure process, the overall process can be simplified, and the manufacturing time and cost can be saved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A microlens mask used as an exposure mask for patterning a microlens photoresist layer, the microlens mask comprising a plurality of patterns forming a pentagonal or hexagonal array, sides of the patterns being adjacent to each other and spaced apart by an interval.

2. The microlens mask according to claim 1, wherein the patterns forming the pentagonal or hexagonal array are pentagonal and the array has a snow crystal pattern.

3. The microlens mask according to claim 1, wherein the patterns forming the pentagonal or hexagonal array are hexagonal and the array has a honey comb pattern.

4. The microlens mask according to claim 1, wherein the interval is about 0.045 μm or about 0.055 μm.

5. A method for forming a microlens, comprising:
forming an insulating layer and a metal pad on a semiconductor substrate for an image sensor, the metal pad being exposed through the insulating layer to the outside;
forming a passivation layer on the insulating layer;
forming a color filter layer on the insulating layer through the passivation layer;
forming a microlens photoresist layer over an entire surface of the semiconductor substrate including the color filter layer, the passivation layer, and the exposed metal pad;
forming a microlens mask on the microlens photoresist layer corresponding to the color filter layer, the microlens mask comprising a plurality of patterns forming a pentagonal or hexagonal array, sides of the patterns being adjacent to each other and spaced apart by an interval;
performing a one-time exposure process at a light intensity of about 450/0 to about 550/0 (dose/focus);
patterning the microlens photoresist layer on the color filter layer; and
reflowing the patterned microlens photoresist layer to form the microlens.

6. The method according to claim 5, wherein the patterns forming the pentagonal or hexagonal array are pentagonal and the array has a snow crystal pattern.

7. The method according to claim 5, wherein the patterns forming the pentagonal or hexagonal array are hexagonal and the array has a honey comb pattern.

8. The method according to claim 5, wherein the interval is about 0.045 μm to about 0.055 μm.

9. The method according to claim 5, wherein the light intensity of the exposure process is adjusted to completely remove the microlens photoresist layer on the metal pad.

10. The method according to claim 5, wherein the insulating layer comprises an Undoped Silicate Glass (USG), and the passivation layer comprises a Silicon Nitride (SiN) layer.

11. The method according to claim 5, wherein the patterning of the microlens photoresist layer comprises:
removing the microlens mask; and
performing a development process to remove the photoresist layer exposed during the one-time exposure process.
